(19) United States
(12) Patent Application Publication
(10) Pub. No.: US 2025/0081683 A1
(43) Pub. Date: Mar. 6, 2025

(54) DISPLAY DEVICE

(71) Applicant: Samsung Display Co., LTD., Yongin-si (KR)

(72) Inventors: SEUNG-WON PARK, Yongin-si (KR); KYUNGSIG LEE, Yongin-si (KR); JUO NAM, Yongin-si (KR); KAWON PAK, Yongin-si (KR); TAEKJOON LEE, Yongin-si (KR); SEUNGHEE JANG, Yongin-si (KR); JAEBOK CHANG, Yongin-si (KR)

(73) Assignee: Samsung Display Co., LTD., Yongin-si (KR)

(21) Appl. No.: 18/804,931

(22) Filed: Aug. 14, 2024

(30) Foreign Application Priority Data
Aug. 30, 2023 (KR) 10-2023-0114431

(51) Int. Cl. H01L 33/50; H01L 25/075

(52) U.S. Cl. CPC H10H 20/8512; H01L 25/0753; H10H 20/0361

(57) ABSTRACT

A display device includes a first light emitting element group including at least one first light emitting element emitting a first light having a central wavelength greater than 450 nm and less than about 485 nm, a second light emitting element group including at least one second light emitting element emitting a second light having a central wavelength of about 450 nm or less, a third light emitting element group including at least one third light emitting element emitting a third light having a central wavelength of about 450 nm or less, and a color conversion layer disposed on the first, the second, and the third light emitting element group and including a first color conversion pattern which converts the second light emitted from the second light emitting element group and a second color conversion pattern which converts the third light emitted from the third light emitting element group.

### CROSS REFERENCE TO RELATED APPLICATION(S)

This application claims priority to and benefits of Korean Patent Application No. 10-2023-0114431 under 35 U.S.C. § 119, filed on Aug. 30, 2023, in the Korean Intellectual Property Office (KIPO), the entire contents of which are incorporated herein by reference.

### BACKGROUND

### 1. Technical Field

The disclosure relates to a display device including a color conversion layer.

### 2. Description of the Related Art

As information technology develops, the importance of a display device as a connection medium between a user and information is being highlighted.

Recently, display devices including a light emitting element and a color conversion layer are being studied. The color conversion layer may convert a color (or a wavelength) of light emitted from the light emitting element.

### SUMMARY

Embodiments provide a display device with improved light efficiency and display quality.

A display device according to an embodiment may include a first light emitting element group including at least one first light emitting element which emits a first light having a central wavelength greater than about 450 nm and less than about 485 nm, a second light emitting element group including at least one second light emitting element which emits a second light having a central wavelength less than or equal to about 450 nm, a third light emitting element group including at least one third light emitting element which emits a third light having a central wavelength less than or equal to about 450 nm, and a color conversion layer disposed on the first light emitting element group, the second light emitting element group, and the third light emitting element group and including a first color conversion pattern which converts a light emitted from the second light emitting element group and a second color conversion pattern which converts a light emitted from the third light emitting element group.

In an embodiment, the color conversion layer may further include a light transmission pattern which transmits a light emitted from the first light emitting element group,

In an embodiment, the light transmission pattern may overlap the first light emitting element group in a plan view, the first color conversion pattern may overlap the second light emitting element group in the plan view, and the second color conversion pattern may overlap the third light emitting element group in the plan view.

In an embodiment, the light transmission pattern may include a first scatterer, and each of the first color conversion pattern and the second color conversion pattern may include a quantum dot.

In an embodiment, each of the first color conversion pattern and the second color conversion pattern may further include a second scatterer.

In an embodiment, the first color conversion pattern may convert the light emitted from the second light emitting element group into green light, and the second color conversion pattern may convert the light emitted from the third light emitting element group into red light.

In an embodiment, a light conversion efficiency of the first color conversion pattern with respect to the light emitted from the second light emitting element group may be greater than or equal to about 30%, and a light conversion efficiency of the second color conversion pattern with respect to the light emitted from the third light emitting element group may be greater than or equal to about 35%.

In an embodiment, the central wavelength of the first light emitted by the at least one first light emitting element may be in a range of about 460 nm to about 470 nm.

In an embodiment, a color matching rate of the display device may be greater than or equal to about 90%.

In an embodiment, the display device may further include a color filter layer disposed on the color conversion layer.

In an embodiment, each of the at least one first light emitting element, the at least one second light emitting element, and the at least one third light emitting element may be an ultra-small light emitting element.

In an embodiment, the central wavelength of the second light emitted from the at least one second light emitting element and the central wavelength of the third light emitted from the at least one third light emitting element may be same.

In an embodiment, the central wavelength of the second light emitted from the at least one second light emitting element and the central wavelength of the third light emitted from the at least one third light emitting element may be different from each other.

In an embodiment, the second light emitting element group may further include the at least one third light emitting element, and the third light emitting element group may further include the at least one second light emitting element.

A display device according to an embodiment may include a first light emitting element group including at least one first light emitting element which emits a first light having a central wavelength greater than about 450 nm and less than about 485 nm, a second light emitting element group including at least one second light emitting element which emits a second light having a central wavelength greater than or equal to about 500 nm, a third light emitting element group including at least one third light emitting element which emits a third light having a central wavelength less than or equal to about 450 nm, and a color conversion layer disposed on the first light emitting element group, the second light emitting element group, and the third light emitting element group and including a color conversion pattern which converts a light emitted from the third light emitting element group.

In an embodiment, the color conversion layer may further include a first light transmission pattern which transmits the first light emitted from the first light emitting element group and a second light transmission pattern which transmits the second light emitted from the second light emitting element group.

In an embodiment, the first light transmission pattern may overlap the first light emitting element group in a plan view, the second light transmission pattern may overlap the second light emitting element group in the plan view, and the color conversion pattern may overlap the third light emitting element group in the plan view.

In an embodiment, each of the first light transmission pattern and the second light transmission pattern may include a first scatterer, and the color conversion pattern may include a quantum dot and a second scatterer.

In an embodiment, the central wavelength of the first light emitted from the at least one first light emitting element may be in a range of about 460 nm to about 470 nm.

In an embodiment, a color matching rate of the display device may be greater than or equal to about 90%.

In an embodiment, the display device may further include a color filter layer disposed on the color conversion layer.

In an embodiment, each of the at least one first light emitting element, the at least one second light emitting element, and the at least one third light emitting element may be an ultra-small light emitting element.

In the display device according to embodiments, the display device may include a first light emitting element group including light emitting elements that emit a light having a center wavelength of more than about 450 nm and less than about 485 nm, a second light emitting element group including the light emitting elements that emit a light having a central wavelength of about 450 nm or less. The display device may include a color conversion pattern that converts light emitted from the second light emitting element group. The display device may include a light transmission pattern that transmits light emitted from the first light emitting element group.

As the second light emitting element group corresponding to the color conversion pattern emits a light having a center wavelength of about 450 nm or less, a light conversion efficiency of the color conversion pattern with respect to a light emitted from the second light emitting element group may be improved.

Even in case that a central wavelength of the light emitted from the second light emitting element group is about 450 nm or less, as the first light emitting element group corresponding to the light transmission pattern emits a light having a center wavelength of more than about 450 nm and less than about 485 nm, the display device may have an improved color matching rate.

Therefore, according to embodiments, a light conversion efficiency of the color conversion pattern may be improved without reducing the color matching rate of the display device. Accordingly, a light efficiency and a display quality of the display device may be improved.

It is to be understood that both the foregoing general description and the following detailed description are exemplary and explanatory and are intended to provide further explanation of the disclosure.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to an embodiment.

FIG. 2 is a schematic cross-sectional view illustrating the display device of FIG. 1.

FIG. 3 is a plan view illustrating the light emitting element layer of FIG. 2.

FIG. 4 is a schematic cross-sectional view taken along line I-I′ of FIG. 1.

FIG. 5 is a plan view illustrating a display device according to an embodiment.

FIG. 6 is a plan view illustrating a light emitting element layer included in the display device of FIG. 5.

FIG. 7 is a schematic cross-sectional view taken along line II-II′ in FIG. 5.

FIG. 8 is a schematic cross-sectional view taken along line III-III′ in FIG. 5.

FIG. 9 is a plan view illustrating a display device according to an embodiment.

FIG. 10 is a plan view illustrating a light emitting element layer included in the display device of FIG. 9.

FIG. 11 is a schematic cross-sectional view taken along line IV-IV′ of FIG. 9.

FIG. 12 is a plan view illustrating a display device according to an embodiment.

FIG. 13 is a plan view illustrating a light emitting element layer included in the display device of FIG. 12.

FIG. 14 is a schematic cross-sectional view taken along line V-V′ of FIG. 12.

### DETAILED DESCRIPTION OF THE EMBODIMENTS

The embodiments now will be described more fully hereinafter with reference to the accompanying drawings, in which various embodiments are shown. The disclosure may, however, be embodied in many different forms, and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

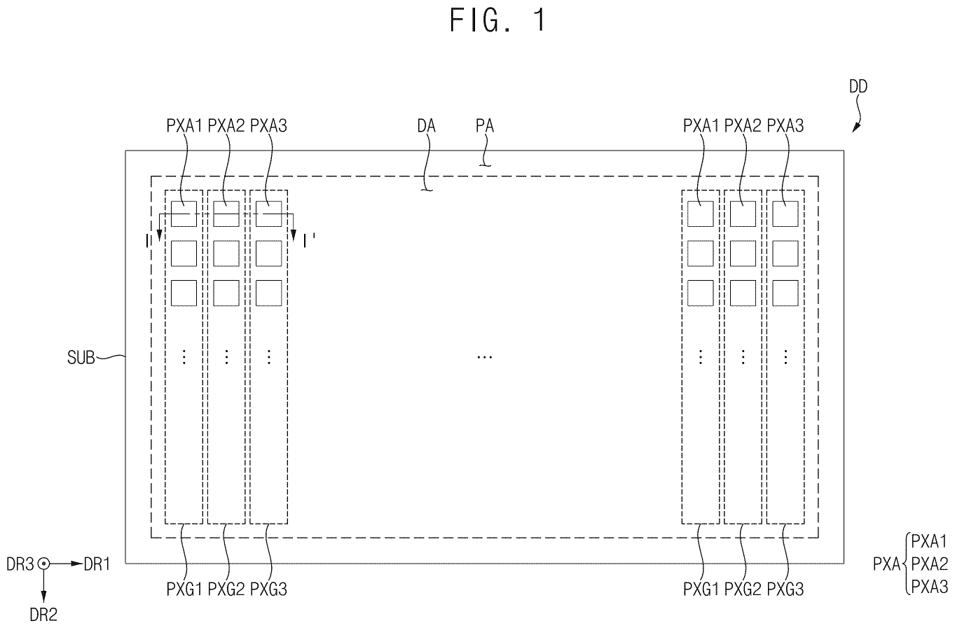

FIG. 1 is a plan view illustrating a display device according to an embodiment.

Referring to FIG. 1, a display device DD may have various shapes. In an embodiment, the display device DD may be provided in a rectangular shape in a plan view, but the display device DD is not limited thereto. For example, the display device DD may have a circular or oval shape in a plan view. The display device DD may include angled corners and/or curved corners. For convenience of explanation, FIG. 1 illustrates an embodiment that the display device DD has a rectangular shape with a pair of long sides and a pair of short sides, and an extension direction of the long sides is indicated as a first direction DR1, an extension direction of the short sides is indicated as a second direction DR2, and a direction perpendicular to the extension direction of the long sides and the extension direction of the short side is indicated as a third direction DR3.

The display device DD may include a display area DA and a peripheral area PA. The display area DA may be an area that can display an image by generating light or adjusting a transmittance of light provided from an external light source.

Multiple pixels may be arranged in the display area DA. For example, the display area DA may include multiple pixel areas PXA in which the pixels are arranged. The pixels (i.e., pixel areas PXA) may be arranged in a matrix form along the first direction DR1 and the second direction DR2.

The peripheral area PA may be located adjacent to the display area DA. For example, the peripheral area PA may entirely surround the display area DA in a plan view. Various wires and drivers connected to the pixels may be disposed in the peripheral area PA.

The pixel areas PXA may include first pixel areas PXA1, second pixel areas PXA2, and third pixel areas PXA3. For example, light of the same color may be emitted from all of the first pixel areas PXA1, light of the same color may be emitted from all of the second pixel areas PXA2, and light of the same color may be emitted from the third pixel areas PXA3.

Accordingly, a set of the first pixel areas PXA1 may be defined as a first pixel group PXG1 that emits light of a color, and a set of the second pixel areas PXA2 may be defined as the second pixel group PXG2 that emits light of a color, and a set of the third pixel areas PXA3 may be defined as a third pixel group PXG3 that emits light of a color.

In an embodiment, a red light, a green light, and a blue light may be selectively emitted from the first pixel areas PXA1, second pixel areas PXA2, and third pixel areas PXA3. For example, a blue light may be emitted from the first pixel areas PXA1, a green light may be emitted from the second pixel areas PXA2, and a red light may be emitted from the third pixel areas PXA3. For example, the first pixel group PXG1 may be a set of the first pixel areas PXA1 that emit a blue light, the second pixel group PXG2 may be a set of the second pixel areas PXA2 that emit a green light, and the third pixel group PXG3 may be a set of the third pixel areas PXA3 that emit a red light. However, the disclosure is not necessarily limited thereto.

A planar arrangement of the pixel areas PXA illustrated in FIG. 1 is only an embodiment, but the disclosure is not limited thereto, and the arrangement of the pixel areas PXA may be variously changed according to embodiments.

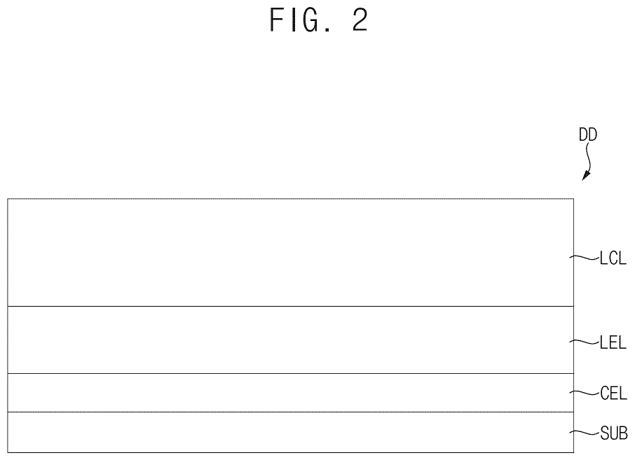

FIG. 2 is a schematic cross-sectional view illustrating the display device of FIG. 1.

Referring to FIGS. 1 and 2, the display device DD may include a substrate SUB, a circuit element layer CEL, a light emitting element layer LEL, and a light conversion layer LCL.

The substrate SUB may include a transparent or opaque material. For example, the substrate SUB may include glass, quartz, plastic, or the like. These can be used alone or in combination with each other. In case that the substrate SUB is made of rigid glass, the display device DD may be implemented as a rigid display device. In case that the substrate SUB is made of flexible plastic, the display device DD may be implemented as a flexible display device.

The circuit element layer CEL may be disposed on the substrate SUB. The circuit element layer CEL may include at least one transistor and signal lines connected to the transistor. For example, the transistor may include an active pattern, a gate electrode, a source electrode, and a drain electrode and may have a structure in which the active pattern and the gate electrode are sequentially stacked with an insulating layer interposed between the gate electrode and the active pattern. The active pattern may include a silicon semiconductor material, an oxide semiconductor material, or an organic semiconductor material. Each of the gate electrode, the source electrode, and the drain electrode may include a metal, an alloy, a conductive metal oxide, a transparent conductive material, or the like.

The light emitting element layer LEL may be disposed on the circuit element layer CEL. The light emitting device layer LEL may include a light emitting element that emits light. The light emitting element may be driven by the transistor and the signal lines included in the circuit element layer CEL. In an embodiment, the light emitting element may be an ultra-small light emitting element such as a micro-scale light emitting element or a nano-scale light emitting element. For example, the light emitting element may be an ultra-small light emitting element such as a micro-scale light emitting element.

According to an embodiment, an encapsulation layer may be disposed on the light emitting element layer LEL. The encapsulation layer may include at least one inorganic layer and at least one organic layer. The encapsulation layer may prevent external air and/or moisture from penetrating into the light emitting element layer LEL and the circuit element layer CEL.

The light conversion layer LCL may be disposed on the light emitting element layer LEL. The light conversion layer LCL may include a color conversion layer. For example, the light conversion layer LCL may convert a color (or a wavelength) of light emitted from the light emitting element layer LEL by the color conversion layer. In an embodiment, the light conversion layer LCL may selectively transmit light of a specific color (or wavelength) by a color filter layer. In an embodiment, the light conversion layer LCL may be formed through a continuous process on a surface of the light emitting element layer LEL. However, the disclosure is not necessarily limited thereto, and the light conversion layer LCL may be formed separately and bonded to the light emitting element layer LEL through a separate process. Hereinafter, for convenience of explanation, an embodiment that the light conversion layer LCL is formed through a continuous process on a surface of the light emitting element layer LEL will be explained.

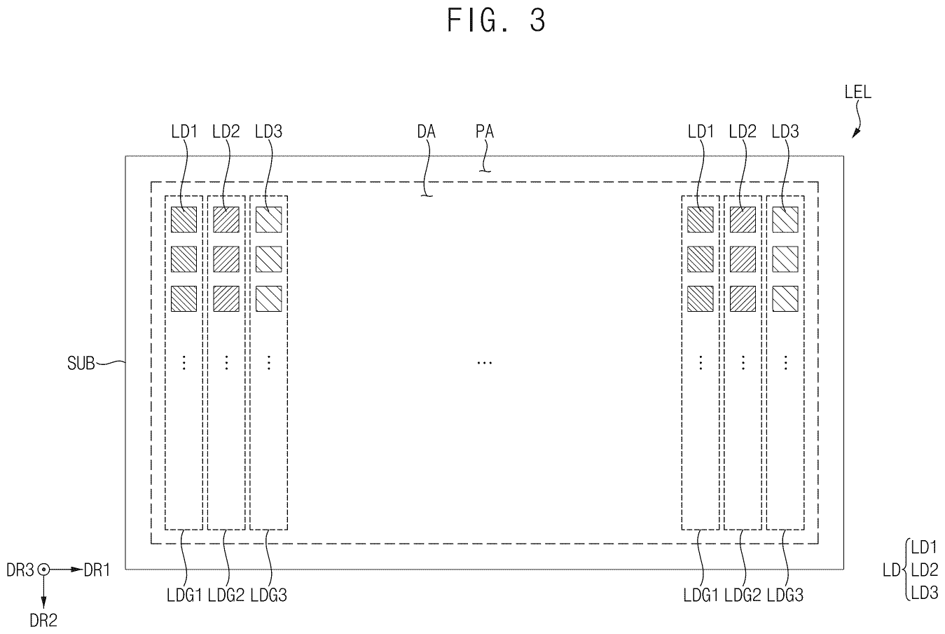

FIG. 3 is a plan view illustrating the light emitting element layer of FIG. 2.

Further referring to FIG. 3, as the display device DD has the display area DA and the peripheral area PA, the light emitting element layer LEL may also be divided into the display area DA and the peripheral area PA.

The light emitting element layer LEL may include light emitting elements LD. The light emitting elements LD may include first light emitting elements LD1, second light emitting elements LD2, and third light emitting elements LD3.

The light emitting elements LD may be disposed in the display area DA. For example, the light emitting elements LD may be disposed in each of the pixel areas PXA of FIG. 1. For example, a set of light emitting elements disposed in the first pixel areas PXA1 among the light emitting elements LD may be defined as a first light emitting element group LDG1. A set of light emitting elements disposed in the second pixel areas PXA2 among the light emitting elements LD may be defined as a second light emitting element group LDG2. A set of light emitting elements disposed in the third pixel areas PXA3 among the light emitting elements LD may be defined as a third light emitting element group LDG3. For example, each of the first light emitting element group LDG1, the second light emitting element group LDG2, and the third light emitting element group LDG3 may include at least one light emitting element.

In an embodiment, as illustrated in FIG. 3, the first light emitting element group LDG1 may be a set of the first light emitting elements LD1, the second light emitting element group LDG2 may be a set of the second light emitting elements LD2, and the third light emitting element group LDG3 may be a set of third light emitting elements LD3. In other words, in an embodiment, the first light emitting elements LD1 may be disposed in the first pixel areas PXA1, the second light emitting elements LD2 may be disposed in the second pixel areas PXA2, and the third light emitting elements LD3 may be disposed in the third pixel areas PXA3. However, the disclosure is not necessarily limited thereto.

A planar arrangement of the light emitting elements LD illustrated in FIG. 3 is only an embodiment and may be variously changed according to embodiments.

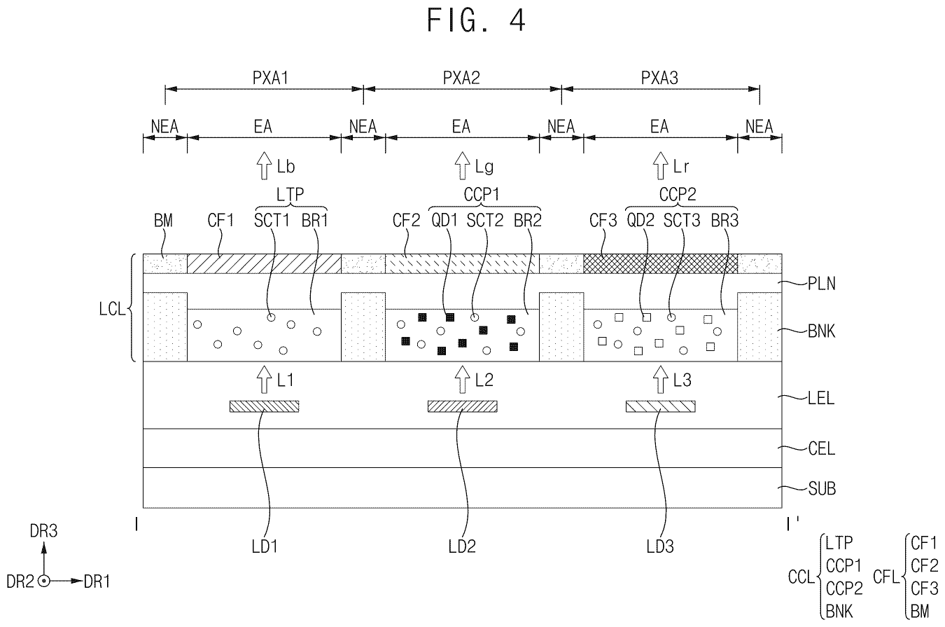

FIG. 4 is a schematic cross-sectional view taken along line I-I′ of FIG. 1.

Further referring to FIG. 4, the circuit element layer CEL, the light emitting element layer LEL, and the light conversion layer LCL may be disposed on the substrate SUB.

The light emitting elements LD may be disposed in an emission area EA. In an embodiment, the first light emitting elements LD1 may be disposed in the emission area EA of the first pixel areas PXA1, the second light emitting elements LD2 may be disposed in the emission area EA of the second pixel areas PXA2, and the third light emitting elements LD3 may be disposed in the emission area EA of the third pixel areas PXA3.

All of the first light emitting elements LD1 may emit light of the same component (e.g., center wavelength, color, etc.), all of the second light emitting elements LD2 may emit light of the same component, and all of the third light emitting elements LD3 may emit light of the same component.

For example, each of the first light emitting elements LD1 may emit a first light L1, each of the second light emitting elements LD2 may emit a second light L2, and each of the third light emitting elements LD3 may emit a third light L3. In an embodiment, all of the first light L1, the second light L2, and the third light L3 may be blue light. However, the disclosure is not necessarily limited thereto.

In an embodiment, a central wavelength of the second light L2 and a central wavelength of the third light L3 may be shorter than a central wavelength of the first light L1. For example, each of the second light L2 and the third light L3 may have a shorter wavelength than a wavelength of the first light L1.

In an embodiment, the central wavelength of the first light L1 emitted from the first light emitting elements LD1 may be greater than about 450 nm and less than about 485 nm. In an embodiment, each of the central wavelength of the second light L2 emitted from the second light emitting elements LD2 and the central wavelength of the third light L3 emitted from the third light emitting elements LD3 may be less than or equal to about 450 nm.

For example, the central wavelength of the first light L1 emitted from the first light emitting elements LD1 may be in a range of about 460 nm to about 470 nm. For example, the central wavelength of the first light L1 emitted from the first light emitting elements LD1 may be in a range of about 465 nm to about 468 nm. For example, each of the central wavelength of the second light L2 emitted from the second light emitting elements LD2 and the central wavelength of the third light L3 emitted from the third light emitting elements LD3 may be in a range of about 360 nm to about 450 nm. For example, each of the central wavelength of the second light L2 emitted from the second light emitting elements LD2 and the central wavelength of the third light L3 emitted from the third light emitting elements LD3 may be in a range of about 400 nm to about 450 nm.

For example, the first light emitting elements LD1 may emit the first light L1 of blue having the central wavelength greater than about 450 nm and less than about 485 nm, the second light emitting elements LD2 may emit the second light L2 of blue having the central wavelength less than or equal to about 450 nm, and the third light emitting elements LD3 may emit the third light L3 of blue having a central wavelength less than or equal to about 450 nm.

As the second light emitting elements LD2 emit the second light L2 having a central wavelength less than or equal to about 450 nm, a light conversion efficiency of a color conversion pattern described below with respect to the second light L2 may be improved. Likewise, as the third light emitting elements LD3 emit the third light L3 having a center wavelength less than or equal to about 450 nm, a light conversion efficiency of a color conversion pattern described below with respect to the third light L3 may be improved. This will be described in more detail below.

Even in case that each of the central wavelength of the second light L2 and the central wavelength of the third light L3 is less than or equal to about 450 nm, as the first light emitting elements LD1 emit the first light L1 having a central wavelength greater than about 450 nm and less than 485 nm, the display device DD may have an improved color matching rate. For example, the display device DD may have a BT2020 color matching rate of greater than or equal to about 90%. This will be described in more detail below. The BT2020 color matching rate may be a ratio of a variation area formed by variation coordinates, which are coordinates of an actually implemented color, to a reference area formed by reference coordinates of a color standard representing UHD (4K).

In an embodiment, the central wavelength of the second light L2 and the central wavelength of the third light L3 may be the same. However, the disclosure is not necessarily limited thereto, and in an embodiment, the central wavelength of the second light L2 and the central wavelength of the third light L3 may be different from each other. For example, the central wavelength of the second light L2 may be shorter than the central wavelength of the third light L3. For example, the central wavelength of the third light L3 may be shorter than the central wavelength of the second light L2.

The light conversion layer LCL may be disposed on the light emitting element layer LEL. In an embodiment, the light conversion layer LCL may include a color conversion layer CCL, a planarization layer PLN, and a color filter layer CFL.

The color conversion layer CCL may include a light transmission pattern LTP, a first color conversion pattern CCP1, a second color conversion pattern CCP2, and a bank BNK.

The bank BNK may be disposed on the light emitting element layer LEL. The bank BNK may surround the emission area EA in a plan view. The bank BNK may provide a space in which the light transmission pattern LTP, the first color conversion pattern CCP1, and the second color conversion pattern CCP2 are formed. Accordingly, the bank BNK may have a grid shape or a matrix shape in a plan view. In an embodiment, the bank BNK may include an organic material. In an embodiment, the bank BNK may further include a light blocking material. For example, the bank BNK may include a light blocking material such as black pigment, dye, carbon black, or the like. The bank BNK may overlap a non-emission area NEA in a plan view. In an embodiment, the bank BNK may also be omitted.

In an embodiment, the light transmission pattern LTP may be disposed in the first pixel areas PXA1. Specifically, the light transmission pattern LTP may be disposed in the emission area EA of the first pixel areas PXA1. Accordingly, the light transmission pattern LTP may overlap the first light emitting element group LDG1 in a plan view. For example, a light emitted from the first light emitting element group LDG1 may be incident on the light transmission pattern LTP. For example, the first light L1 emitted from the first light emitting elements LD1 defining the first light emitting element group LDG1 may be incident on the light transmission pattern LTP.

The light transmission pattern LTP may transmit a light emitted from the first light emitting element group LDG1. For example, the light transmission pattern LTP may emit a light having substantially the same components (e.g., center wavelength, color, etc.) as a light emitted from the first light emitting element group LDG1.

For example, the light transmission pattern LTP may transmit the first light L1 emitted from the first light emitting elements LD1 defining the first light emitting element group LDG1 without conversion. For example, the light transmission pattern LTP may emit a blue light Lb having substantially the same components (e.g., center wavelength, color, etc.) as the first light L1 emitted from the first light emitting elements LD1.

In an embodiment, the light transmission pattern LTP may include a first base resin BR1 and a first scatterer SCT1.

The first scatterer SCT1 may increase an optical path by scattering a light emitted from the first light emitting element group LDG1 and incident on the light transmission pattern LTP. The first scatterer SCT1 may include a metal oxide. For example, the first scatterer SCT1 may include TiO₂, ZrO₂, Al₂O₃, In₂O₃, ZnO, SnO₂, Sb₂O₃, ITO, or the like. These can be used alone or in combination with each other.

The first scatterer SCT1 may be dispersed in the first base resin BR1. For example, the first base resin BR1 may include an epoxy resin, an acrylic resin, a phenol resin, a melamine resin, a cardo resin, an imide resin, or the like. These can be used alone or in combination with each other.

In an embodiment, the first color conversion pattern CCP1 may be disposed in the second pixel areas PXA2. Specifically, the first color conversion pattern CCP1 may be disposed in the emission area EA of the second pixel areas PXA2. Accordingly, the first color conversion pattern CCP1 may overlap the second light emitting element group LDG2 in a plan view. For example, a light emitted from the second light emitting element group LDG2 may be incident on the first color conversion pattern CCP1. For example, the second light L2 emitted from the second light emitting elements LD2 defining the second light emitting element group LDG2 may be incident on the first color conversion pattern CCP1.

The first color conversion pattern CCP1 may emit a light having a different component (e.g., center wavelength, color, etc.) from a light emitted from the second light emitting element group LDG2. In an embodiment, the first color conversion pattern CCP1 may convert a light emitted from the second light emitting element group LDG2 into a green light Lg.

For example, the first color conversion pattern CCP1 may convert the second light L2 emitted from the second light emitting elements LD2 defining the second light emitting element group LDG2 into the green light Lg. In other words, the first color conversion pattern CCP1 may emit the green light Lg having a different component (e.g., center wavelength, color, etc.) from the second light L2 emitted from the second light emitting elements LD2.

In an embodiment, the first color conversion pattern CCP1 may include a second base resin BR2 and a first color conversion particle QD1.

The first color conversion particle QD1 may convert a color (or a wavelength) of a light emitted from the second light emitting element group LDG2 and incident on the first color conversion pattern CCP1. For example, the first color conversion particle QD1 may include quantum dots that absorb a blue light and emit a green light. The quantum dots may include a semiconductor material having nanocrystals. The quantum dots may have a bandgap depending on their composition and size. Accordingly, the quantum dots may absorb an incident light and emit light having a different color (or wavelength) than the incident light.

The first color conversion particles QD1 may be dispersed in the second base resin BR2. For example, the second base resin BR2 may include an epoxy resin, an acrylic resin, a phenol resin, a melamine resin, a cardo resin, an imide resin, or the like. These can be used alone or in combination with each other.

In an embodiment, the first color conversion pattern CCP1 may further include a second scatterer SCT2 dispersed in the second base resin BR2. The second scatterer SCT2 may increase an optical path by scattering a light emitted from the second light emitting element group LDG2 and incident on the first color conversion pattern CCP1. The second scatterer SCT2 may include a metal oxide. For example, the second scatterer SCT2 may include TiO₂, ZrO₂, Al₂O₃, In₂O₃, ZnO, SnO₂, Sb₂O₃, ITO, or the like. These can be used alone or in combination with each other.

In an embodiment, the second color conversion pattern CCP2 may be disposed in the third pixel areas PXA3. Specifically, the second color conversion pattern CCP2 may be disposed in the emission area EA of the third pixel areas PXA3. Accordingly, the second color conversion pattern CCP2 may overlap the third light emitting element group LDG3 in a plan view. For example, a light emitted from the third light emitting device group LDG3 may be incident on the second color conversion pattern CCP2. For example, the third light L3 emitted from the third light emitting elements LD3 defining the third light emitting element group LDG3 may be incident on the second color conversion pattern CCP2.

The second color conversion pattern CCP2 may emit light having a different component (e.g., center wavelength, color, etc.) from a light emitted from the third light emitting element group LDG3. In an embodiment, the second color conversion pattern CCP2 may convert a light emitted from the third light emitting element group LDG3 into a red light Lr.

For example, the second color conversion pattern CCP2 may convert the third light L3 emitted from the third light emitting elements LD3 defining the third light emitting element group LDG3 into the red light Lr. In other words, the second color conversion pattern CCP2 may emit the red light Lr having a different component (e.g., center wavelength, color, etc.) from the third light L3 emitted from the third light emitting elements LD3.

In an embodiment, the second color conversion pattern CCP2 may include a third base resin BR3 and a second color conversion particle QD2.

The second color conversion particle QD2 may convert a color (or a wavelength) of a light emitted from the third light emitting element group LDG3 and incident on the second color conversion pattern CCP2. For example, the second color conversion particle QD2 may include quantum dots that absorb blue light and emit red light. The quantum dots may include a semiconductor material having nanocrystals. The quantum dots may have a bandgap depending on their composition and size. Accordingly, the quantum dots may absorb incident light and emit light having a different color (or wavelength) than the incident light.

The second color conversion particles QD2 may be dispersed in the third base resin BR3. For example, the third base resin BR3 may include an epoxy resin, an acrylic resin, a phenol resin, a melamine resin, a cardo resin, an imide resin, or the like. These can be used alone or in combination with each other.

In an embodiment, the second color conversion pattern CCP2 may further include a third scatterer SCT3 dispersed in the third base resin BR3. The third scatterer SCT3 may increase an optical path by scattering the light emitted from the third light emitting element group LDG3 and incident on the second color conversion pattern CCP2. The third scatterer SCT3 may include a metal oxide. For example, the third scatterer SCT3 may include TiO₂, ZrO₂, Al₂O₃, In₂O₃, ZnO, SnO₂, Sb₂O₃, ITO, or the like. These can be used alone or in combination with each other.

In an embodiment, the planarization layer PLN may be disposed on the color conversion layer CCL. The planarization layer PLN may include an organic material and/or an inorganic material. The planarization layer PLN may compensate for a level difference in the color conversion layer CCL. In an embodiment, the planarization layer PLN may be omitted considering a surface shape of the color conversion layer CCL.

The color filter layer CFL may be disposed on the color conversion layer CCL. The color filter layer CFL may include a first color filter CF1, a second color filter CF2, a third color filter CF3, and a black matrix BM.

The black matrix BM may surround the emission area EA in a plan view. For example, the black matrix BM may overlap the non-emission area NEA in a plan view. In an embodiment, the black matrix BM may include a light blocking material. For example, the black matrix BM may include a light-blocking material such as black pigment, dye, carbon black, or the like. The black matrix BM may prevent color mixing of light emitted from adjacent pixel areas.

The first color filter CF1 may be disposed in the first pixel areas PXA1. Specifically, the first color filter CF1 may be disposed in the emission area EA of the first pixel areas PXA1. Accordingly, the first color filter CF1 may overlap the first light emitting element group LDG1 and the light transmission pattern LTP in a plan view. In an embodiment, the first color filter CF1 may be a blue color filter that selectively transmits the blue light Lb.

The second color filter CF2 may be disposed in the second pixel areas PXA2. Specifically, the second color filter CF2 may be disposed in the emission area EA of the second pixel areas PXA2. Accordingly, the second color filter CF2 may overlap the second light emitting element group LDG2 and the first color conversion pattern CCP1 in a plan view. In an embodiment, the second color filter CF2 may be a green color filter that selectively transmits the green light Lg.

The third color filter CF3 may be disposed in the third pixel areas PXA3. Specifically, the third color filter CF3 may be disposed in the emission area EA of the third pixel areas PXA3. Accordingly, the third color filter CF3 may overlap the third light emitting element group LDG3 and the second color conversion pattern CCP2 in a plan view. In an embodiment, the third color filter CF3 may be a red color filter that selectively transmits the red light Lr.

In FIG. 4, the first color filter CF1, the second color filter CF2, and the third color filter CF3 are illustrated to be spaced apart from each other by the black matrix BM, but the disclosure is not necessarily limited thereto. For example, the first color filter CF1, the second color filter CF2, and the third color filter CF3 may be arranged to overlap each other in the non-emission area NEA in a plan view. The first color filter CF1, the second color filter CF2, and the third color filter CF3 overlap each other in the non-emission area NEA may define a light blocking structure, and the black matrix BM may be omitted.

According to embodiments, the display device DD may include the first light emitting element group LDG1 including the first light emitting elements LD1 that emit the first light L1 having a center wavelength greater than about 450 nm and less than about 485 nm, the second light emitting element group LDG2 including the second light emitting elements LD2 that emit the second light L2 having a central wavelength less than or equal to about 450 nm, and the third light emitting element group LDG3 including the third light emitting elements LD3 that emit the third light (L3) having a central wavelength less than or equal to about 450 nm.

The display device DD may include the light transmission pattern LTP that transmits a light emitted from the first light emitting element group LDG1, the first color conversion pattern CCP1 that converts a light emitted from the second light emitting element group LDG2, and the second color conversion pattern CCP2 that converts a light emitted from the third light emitting element group LDG3.

As the second light emitting element group LDG2 corresponding to the first color conversion pattern CCP1 emits a light having a center wavelength less than or equal to about 450 nm, a light conversion efficiency of the first color conversion pattern CCP1 with respect to a light emitted from the second light emitting element group LDG2 may be improved.

For example, in case that the second light emitting element group LDG2 corresponding to the first color conversion pattern CCP1 emits a light having a center wavelength exceeding 450 nm, a light conversion efficiency of the first color conversion pattern CCP1 with respect to the light emitted from the second light emitting element group LDG2 may be less than about 30%. On the other hand, in case that the second light emitting element group LDG2 corresponding to the first color conversion pattern CCP1 emits a light having a center wavelength less than or equal to about 450 nm, a light conversion efficiency of the first color conversion pattern CCP1 with respect to the light emitted from the second light emitting element group LDG2 may be greater than or equal to about 30%.

As the third light emitting element group LDG3 corresponding to the second color conversion pattern CCP2 emits a light having a center wavelength less than or equal to about 450 nm, a light conversion efficiency of the second color conversion pattern CCP2 with respect to a light emitted from the third light emitting element group LDG3 may be improved.

For example, in case that the third light emitting element group LDG3 corresponding to the second color conversion pattern CCP2 emits a light having a center wavelength exceeding 450 nm, a light conversion efficiency of the second color conversion pattern CCP2 with respect to the light emitted from the third light emitting element group LDG3 may be less than about 35%. On the other hand, in case that the third light emitting element group LDG3 corresponding to the second color conversion pattern CCP2 emits a light having a center wavelength less than or equal to about 450 nm, a light conversion efficiency of the second color conversion pattern CCP2 with respect to the light emitted from the third light emitting element group LDG3 may be greater than or equal to about 35%.

Even in case that a central wavelength of the light emitted from the second light emitting element group LDG2 and a central wavelength of the light emitted from the third light emitting element group LDG3 are less than about 450 nm, as the first light emitting element group LDG1 corresponding to the light transmission pattern LTP emits a light having a center wavelength greater than about 450 nm and less than about 485 nm, the display device DD may have an improved color matching rate.

For example, in case that a central wavelength of the light emitted from the second light emitting element group LDG2 and a central wavelength of the light emitted from the third light emitting element group LDG3 are less than or equal to about 450 nm, and the first light transmission pattern LTP corresponding to the light transmission pattern LTP emits a light having a center wavelength less than about 450 nm, the BT2020 color matching rate of the display device DD may be less than about 90%. On the other hand, in case that a central wavelength of the light emitted from the second light emitting element group LDG2 and a central wavelength of the light emitted from the third light emitting element group LDG3 are less than or equal to about 450, and the first light transmission pattern LTP corresponding to the light transmission pattern LTP emits a light having a center wavelength greater than about 450 nm and less than about 485 nm, the BT2020 color matching rate of the display device DD may be greater than or equal to about 90%.

Therefore, according to embodiments, a light conversion efficiency of the first color conversion pattern CCP1 and the second color conversion pattern CCP2 may be improved without reducing the color matching rate of the display device DD. Accordingly, a light efficiency and a display quality of the display device DD may be improved.

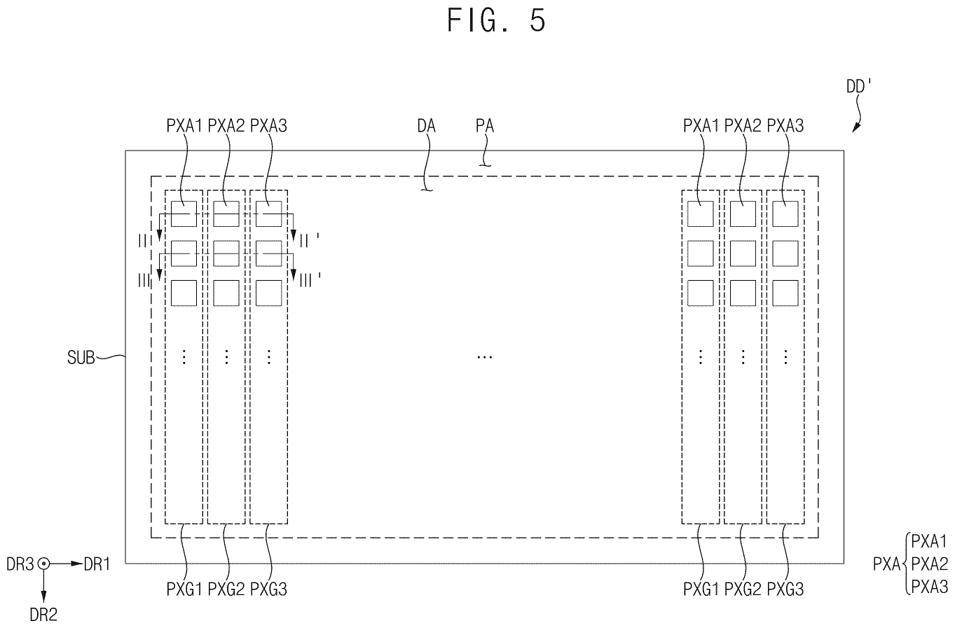

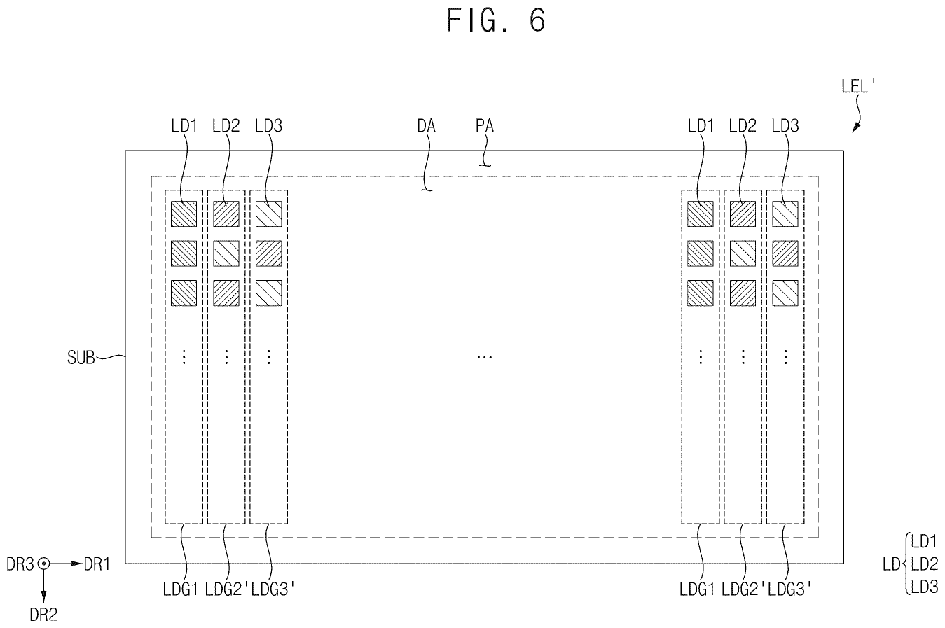

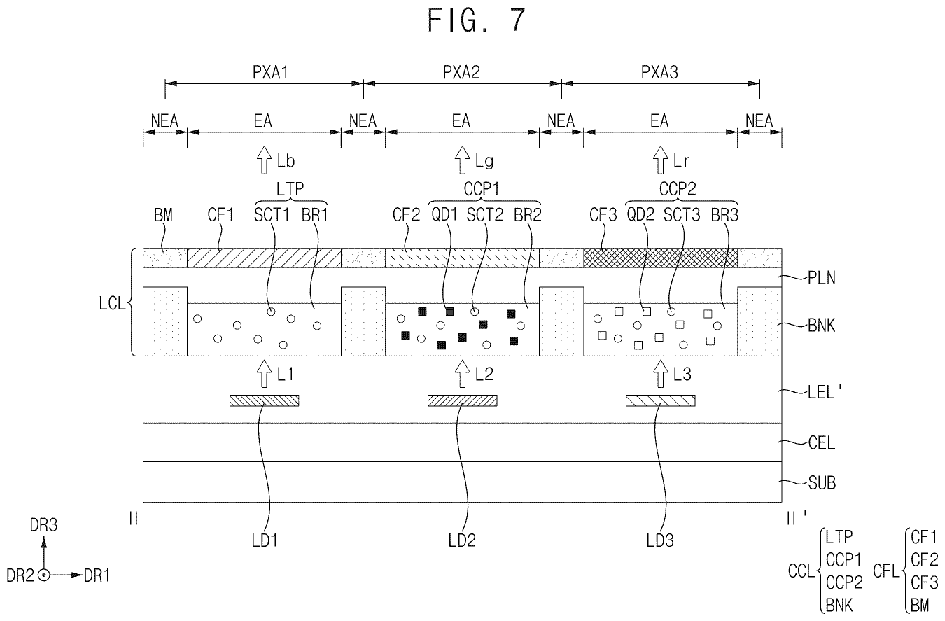

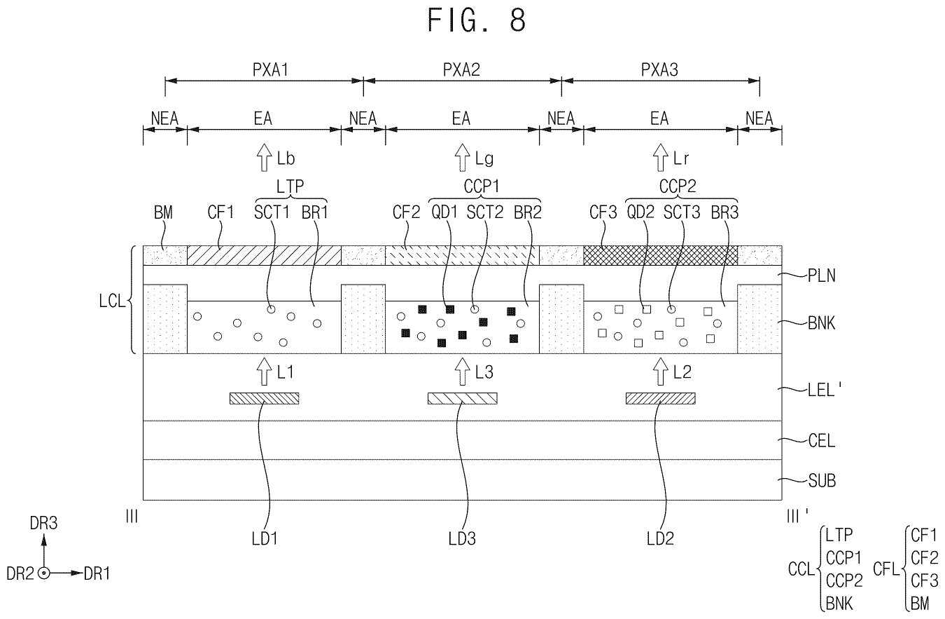

FIG. 5 is a plan view illustrating a display device according to an embodiment. FIG. 6 is a plan view illustrating a light emitting element layer included in the display device of FIG. 5. FIG. 7 is a schematic cross-sectional view taken along line II-II′ in FIG. 5. FIG. 8 is a schematic cross-sectional view taken along line III-III′ in FIG. 5.

Hereinafter, a display device DD′ according to an embodiment will be described with reference to FIGS. 5 to 8.

The display device DD′ described with reference to FIGS. 5 to 8 may be substantially same as the display device DD described with reference to FIGS. 1 to 4 except for a combination of light emitting elements that define each of light emitting element groups.

Therefore, overlapping descriptions will be omitted or simplified.

First, referring to FIGS. 5 and 6, the light emitting element layer LEL′ may include the light emitting elements LD. A set of light emitting elements disposed in the first pixel areas PXA1 among the light emitting elements LD may be defined as the first light emitting element group LDG1. A set of light emitting elements disposed in the second pixel areas PXA2 among the light emitting elements LD may be defined as a second light emitting element group LDG2′. A set of light emitting elements disposed in the third pixel areas PXA3 among the light emitting elements LD may be defined as a third light emitting element group LDG3′. For example, each of the first light emitting element group LDG1, the second light emitting element group LDG2′, and the third light emitting element group LDG3′ may include at least one light emitting element.

In an embodiment, the first light emitting element group LDG1 may be a set of the first light emitting elements LD1. In other words, the first light emitting elements LD1 may be disposed in the first pixel areas PXA1. A detailed description of the first light emitting element group LDG1 will be omitted since it overlaps with the description referring to FIGS. 1 to 4.

In an embodiment, each of the second light-emitting element group LDG2′ and the third light emitting element group LDG3′ may be a combination of at least one of the second light emitting elements LD2 and at least one of the third light emitting elements LD3. For example, the second light emitting element group LDG2′ may be a combination of some of the second light emitting elements LD2 and some of the third light emitting elements LD3, and the third light emitting element group LDG3′ may be a combination of another ones of the second light emitting elements LD2 and another ones of the third light emitting elements LD3. For example, each of the second light emitting element group LDG2′ and the third light emitting element group LDG3′ may include at least one of the second light emitting elements LD2 and at least one of the third light emitting elements LD3.

In other words, in an embodiment, some of the second light emitting elements LD2 may be disposed in corresponding second pixel areas PXA2, and another ones of the second light emitting elements LD2 may be disposed in corresponding the third pixel areas PXA3. Some of the third light emitting elements LD3 may be disposed in corresponding second pixel areas PXA2, and another ones of the third light emitting elements LD3 may be disposed in corresponding third pixel areas PXA3.

A planar arrangement of the light emitting elements LD illustrated in FIG. 6 is only an embodiment and may be variously changed according to embodiments.

Further referring to FIGS. 7 and 8, the circuit element layer CEL, a light emitting element layer LEL′, and the light conversion layer LCL may be disposed on the substrate SUB. A detailed description of the substrate SUB, the circuit element layer CEL, and the light conversion layer LCL will be omitted since it overlaps with the description referring to FIGS. 1 to 4.

In an embodiment, the first light emitting elements LD1 may be disposed in the emission area EA of the first pixel areas PXA1. Some of the second light emitting elements LD2 may be disposed in the emission area EA of the corresponding second pixel areas PXA2, and another ones of the second light emitting elements LD2 may be disposed in the emission area EA of the corresponding third pixel areas PXA3. Some of the third light emitting elements LD3 may be disposed in the emission area EA of the corresponding third pixel areas PXA3, and another ones of the third light emitting elements LD3 may be disposed in the emission area EA of the corresponding second pixel areas PXA2.

As described with reference to FIGS. 1 to 4, all of the first light emitting elements LD1 may emit a light of the same component (e.g., center wavelength, color, etc.), all of the second light emitting elements LD2 may emit a light of the same component, and all of the third light emitting elements LD3 may emit a light of the same component.

In an embodiment, the central wavelength of the first light L1 emitted from the first light emitting elements LD1 may be greater than about 450 nm and less than 485 nm. In an embodiment, each of the central wavelength of the second light L2 emitted from the second light emitting elements LD2 and the central wavelength of the third light L3 emitted from the third light emitting elements LD3 may be less than or equal to about 450 nm.

For example, the central wavelength of the first light L1 emitted from the first light emitting elements LD1 may be in a range of about 460 nm to about 470 nm. For example, the central wavelength of the first light L1 emitted from the first light emitting elements LD1 may be in a range of about 465 nm to about 468 nm. For example, each of the central wavelength of the second light L2 emitted from the second light emitting elements LD2 and the central wavelength of the third light L3 emitted from the third light emitting elements LD3 may be in a range of about 360 nm to about 450 nm. For example, each of the central wavelength of the second light L2 emitted from the second light emitting elements LD2 and the central wavelength of the third light L3 emitted from the third light emitting elements LD3 may be in a range of about 400 nm to about 450 nm.

In the display device DD′ according to an embodiment, a central wavelength of the second light L2 and a central wavelength of the third light L3 may be different from each other. For example, the central wavelength of the second light L2 may be shorter than the central wavelength of the third light L3. For example, the central wavelength of the third light L3 may be shorter than the central wavelength of the second light L2. For example, each of the second light emitting element group LDG2′ and the third light emitting element group LDG3′ may be a combination of light emitting elements that emit light of different center wavelengths from each other.

In the display device DD′ according to an embodiment, as illustrated in FIG. 7, the first color conversion pattern CCP1 may convert the second light L2 emitted from the second light emitting elements LD2 defining the second light emitting element group LDG2′ into a green light Lg. As illustrated in FIG. 8, the first color conversion pattern CCP1 may convert the third light L3 emitted from the third light emitting elements LD3 defining the second light emitting element group LDG2′ into a green light Lg.

As illustrated in FIG. 7, the second color conversion pattern CCP2 may convert the third light L3 emitted from the third light emitting elements LD3 defining the third light emitting element group LDG3′ into a red light. As illustrated in FIG. 8, the third color conversion pattern CCP3 may convert the second light L2 emitted from the second light emitting elements LD2 defining the third light emitting element group LDG3′ into a red light Lr.

According to embodiments, the display device DD′ may include the first light emitting element group LDG1 including the first light emitting elements LD1 that emit the first light L1 having a center wavelength greater than about 450 nm and less than about 485 nm, the second light emitting element group LDG2 which is a combination of the second light emitting elements LD2 that emit the second light L2 having a central wavelength less than or equal to about 450 nm and the third light emitting elements LD3 that emit the third light L3 having a central wavelength less than or equal to about 450 nm, and the third light emitting element group LDG3 which is a combination of the second light emitting elements LD2 that emit the second light L2 having a central wavelength less than or equal to about 450 nm and the third light emitting elements LD3 that emit the third light L3 having a central wavelength less than or equal to about 450 nm.

The display device DD may include the light transmission pattern LTP that transmits a light emitted from the first light emitting element group LDG1, the first color conversion pattern CCP1 that converts a light emitted from the second light emitting element group LDG2′, and the second color conversion pattern CCP2 that converts a light emitted from the third light emitting element group LDG3′.

As the second light emitting element group LDG2′ corresponding to the first color conversion pattern CCP1 emits a light having a center wavelength less than or equal to about 450 nm, a light conversion efficiency of the first color conversion pattern CCP1 with respect to a light emitted from the second light emitting element group LDG2′ may be improved.

As the third light emitting element group LDG3′ corresponding to the second color conversion pattern CCP2 emits a light having a center wavelength less than or equal to about 450 nm, a light conversion efficiency of the second color conversion pattern CCP2 with respect to a light emitted from the third light emitting element group LDG3′ may be improved.

Even in case that a central wavelength of the light emitted from the second light emitting element group LDG2′ and a central wavelength of the light emitted from the third light emitting element group LDG3′ are less than or equal to about 450 nm, as the first light emitting element group LDG1 corresponding to the light transmission pattern LTP emits a light having a center wavelength greater than about 450 nm and less than about 485 nm, the display device DD′ may have an improved color matching rate.

Therefore, according to embodiments, a light conversion efficiency of the first color conversion pattern CCP1 and the second color conversion pattern CCP2 may be improved without reducing the color matching rate of the display device DD′. Accordingly, a light efficiency and a display quality of the display device DD′ may be improved.

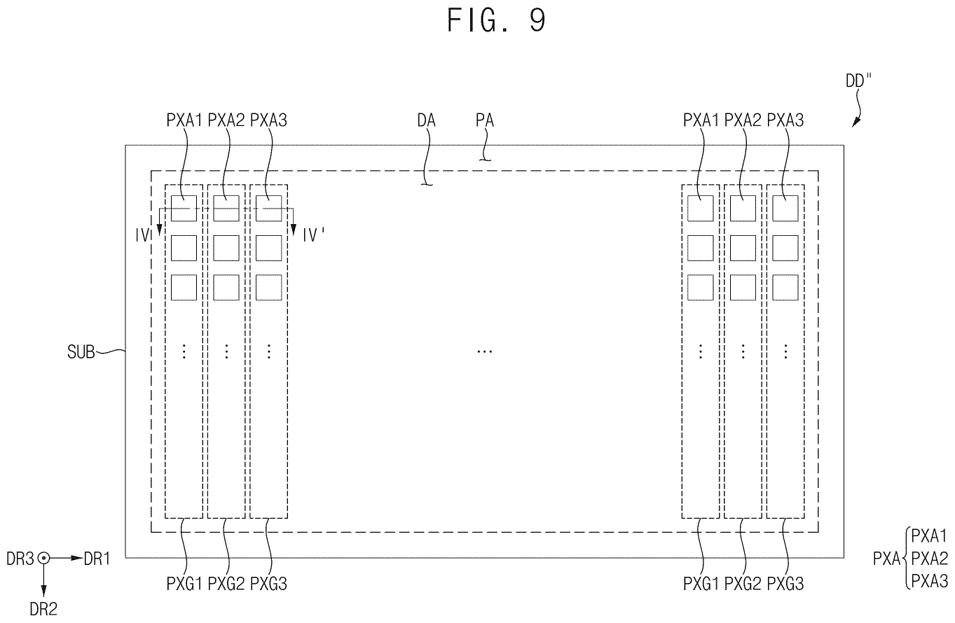

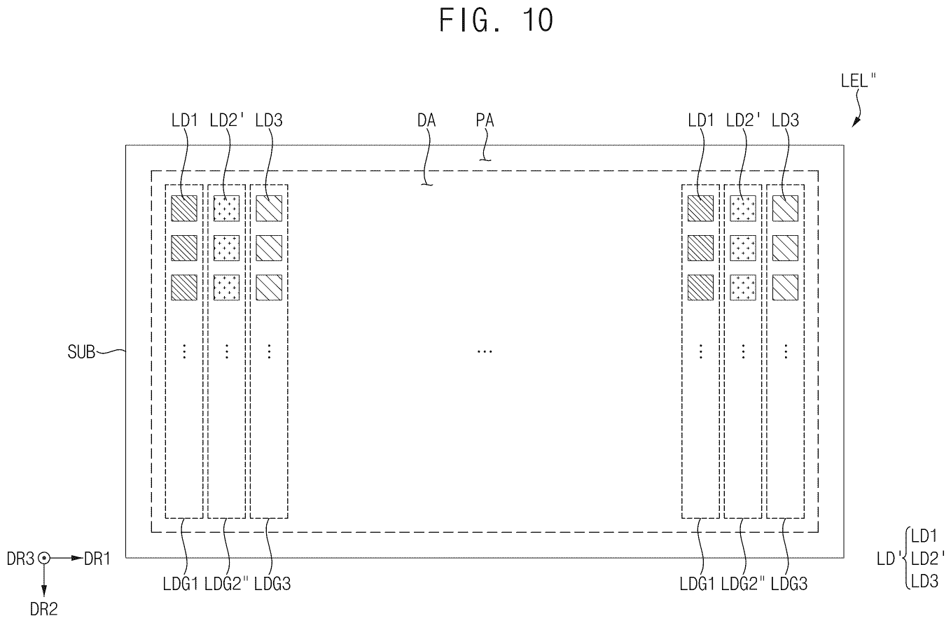

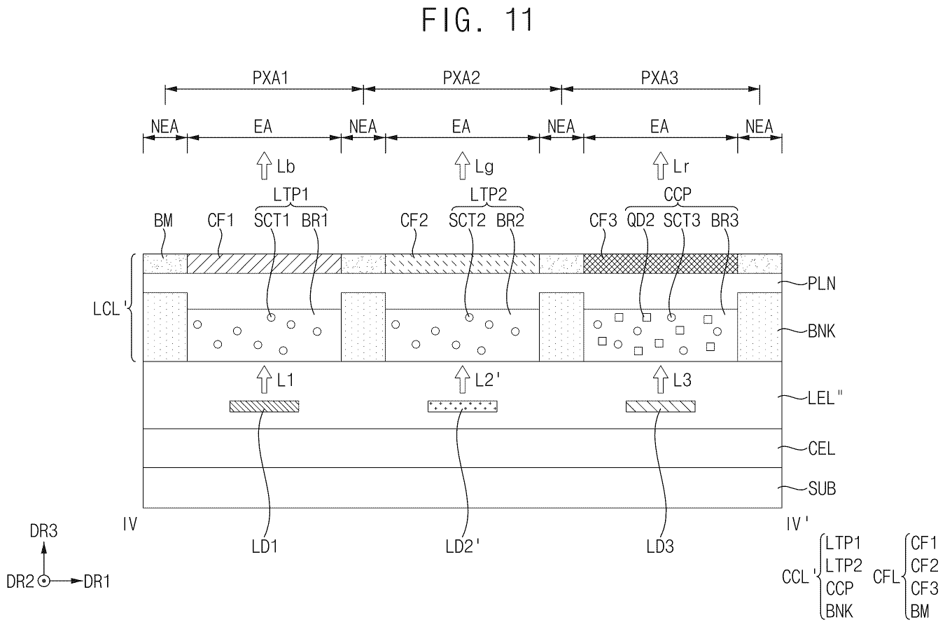

FIG. 9 is a plan view illustrating a display device according to an embodiment. FIG. 10 is a plan view illustrating a light emitting element layer included in the display device of FIG. 9. FIG. 11 is a schematic cross-sectional view taken along line IV-IV′ of FIG. 9.

Hereinafter, a display device DD″ according to an embodiment will be described with reference to FIGS. 9 to 11.

The display device DD″ described with reference to FIGS. 9 to 11 may be substantially the same as the display device DD described with reference to FIGS. 1 to 4 except for including a light emitting element layer LEL″ and a light conversion layer LCL′. Therefore, overlapping descriptions will be omitted or simplified.

First, referring to FIGS. 9 and 10, the display device DD″ may include the light emitting element layer LEL″. The light emitting element layer LEL″ may be substantially same as the light emitting element layer LEL described with reference to FIGS. 1 to 4 except for including light emitting elements LD′ instead of the light emitting elements LD. Therefore, overlapping descriptions will be omitted or simplified.

The light emitting element layer LEL″ may include the light emitting elements LD′. The light emitting elements LD′ may include the first light emitting elements LD1, second light emitting elements LD2′, and the third light emitting elements LD3.

For example, the light emitting elements LD′ may be substantially same as the light emitting elements LD described with reference to FIGS. 3 and 4 except for including the second light emitting elements LD2′ instead of the second light emitting elements LD2. Accordingly, a detailed description of the first light emitting elements LD1 and the third light emitting elements LD3 will be omitted since it overlaps with the description with reference to FIGS. 3 and 4.

In an embodiment, as illustrated in FIG. 10, the first light emitting element group LDG1 may be a set of the first light emitting elements LD1, the second light emitting element group LDG2″ may be a set of the second light emitting elements LD2′, and the third light emitting element group LDG3 may be a set of the third light emitting elements LD3. In other words, in an embodiment, the first light emitting elements LD1 may be disposed in the first pixel areas PXA1, the second light emitting elements LD2′ may be disposed in the second pixel areas PXA2, and the third light emitting elements LD3 may be disposed in the third pixel areas PXA3. However, the disclosure is not necessarily limited thereto.

A planar arrangement of the light emitting elements LD′ illustrated in FIG. 10 is only an embodiment and may be variously changed according to embodiments.

Further referring to FIG. 11, the circuit element layer CEL, the light emitting element layer LEL″, and the light conversion layer LCL′ may be disposed on the substrate SUB. A detailed description of the substrate SUB and the circuit element layer CEL will be omitted since it overlaps with the description referring to FIGS. 1 to 4.

In an embodiment, the second light emitting elements LD2′ may be disposed in the light emitting area EA of the second pixel areas PXA2. All of the second light emitting elements LD2′ may emit light of the same component (e.g., center wavelength, color, etc.).

In an embodiment, the second light emitting elements LD2′ may emit a second light L2′ having a central wavelength greater than or equal to about 500 nm. For example, the second light emitting elements LD2′ may emit the second light L2′ of green having a central wavelength greater than or equal to about 500 nm. For example, the central wavelength of the second light L2′ emitted from the second light emitting elements LD2′ may be in a range of about 500 nm to about 600 nm. For example, the central wavelength of the second light L2′ emitted from the second light emitting elements LD2′ may be in a range of about 515 nm to about 560 nm. For example, the central wavelength of the second light L2′ emitted from the second light emitting elements LD2′ may be in a range of about 530 nm to 540 nm.

For example, in the display device DD″ according to an embodiment, the first light emitting elements LD1 may emit the first light L1 of blue having the central wavelength greater than about 450 nm and less than about 485 nm, the second light emitting elements LD2′ may emit the second light L2′ of green having a center wavelength greater than or equal to about 500 nm, and the third light emitting elements LD3 may emit the third light L3 of blue having a central wavelength less than or equal to about 450 nm.

The light conversion layer LCL′ may be disposed on the light emitting element layer LEL″. In an embodiment, the light conversion layer LCL′ may include a color conversion layer CCL′, the planarization layer PLN, and the color filter layer CFL. For example, the light conversion layer LCL′ may be substantially same as the light conversion layer LCL described with reference to FIGS. 3 and 4 except for including the color conversion layer CCL′ instead of the color conversion layer CCL. Therefore, overlapping descriptions will be omitted or simplified.

The color conversion layer CCL′ may include a first light transmission pattern LTP1, a second light transmission pattern LTP2, a color conversion pattern CCP, and the bank BNK. A detailed description of the bank BNK will be omitted since it overlaps with the description referring to FIG. 4.

The first light transmission pattern LTP1 may have substantially the same structure as the light transmission pattern LTP described with reference to FIG. 4. For example, in an embodiment, the first light transmission pattern LTP1 may include the first base resin BR1 and the first scatterer SCT1.

In an embodiment, the first light transmission pattern LTP1 may be disposed in the emission area EA of the first pixel areas PXA1. Accordingly, the first light transmission pattern LTP1 may overlap the first light emitting element group LDG1 in a plan view.

The first light transmission pattern LTP1 may transmit the first light L1 emitted from the first light emitting elements LD1 defining the first light emitting element group LDG1 without conversion. In other words, the first light transmission pattern LTP1 may emit a blue light Lb having substantially the same components (e.g., center wavelength, color, etc.) as the first light L1 emitted from the first light emitting elements LD1.

The color conversion pattern CCP may have substantially the same structure as the second color conversion pattern CCP2 described with reference to FIG. 4. For example, in an embodiment, the color conversion pattern CCP may include the third base resin BR3 and the second color conversion particle QD2. The color conversion pattern CCP may further include the third scatterer SCT3.

In an embodiment, the color conversion pattern CCP may be disposed in the emission area EA of the third pixel areas PXA3. Accordingly, the color conversion pattern CCP may overlap the third light emitting element group LDG3 in a plan view.

The color conversion pattern CCP may convert the third light L3 emitted from the third light emitting elements LD3 defining the third light emitting element group LDG3 into a red light Lr. In other words, the color conversion pattern CCP may emit the red light Lr having a different component (e.g., center wavelength, color, etc.) from the third light L3 emitted from the third light emitting elements LD3.

The second light transmission pattern LTP2 may be disposed in the second pixel areas PXA2. Specifically, the second light transmission pattern LTP2 may be disposed in the emission area EA of the second pixel areas PXA2. Accordingly, the second light transmission pattern LTP2 may overlap the second light emitting element group LDG2″ in a plan view. For example, light emitted from the second light emitting element group LDG2″ may be incident on the second light transmission pattern LTP2. For example, the second light L2′ emitted from the second light emitting elements LD2′ defining the second light emitting element group LDG2″ may be incident on the second light transmission pattern LTP2.

The second light transmission pattern LTP2 may transmit the light emitted from the second light emitting device group LDG2″. In other words, the second light transmission pattern LTP2 may emit light having substantially the same components (e.g., center wavelength, color, etc.) as the light emitted from the second light emitting element group LDG2″.

For example, the second light transmission pattern LTP2 may transmit the second light L2′ emitted from the second light emitting elements LD2′ defining the second light emitting element group LDG2″ without converting the second light L2′. In other words, the second light transmission pattern LTP2 may emit a green light Lg having substantially the same components (e.g., center wavelength, color, etc.) as the second light L2′ of green emitted from the second light emitting elements LD2′.

In an embodiment, the second light transmission pattern LTP2 may include the second base resin BR2 and the second scatterer SCT2. A detailed description of the second base resin BR2 and the second scatterer SCT2 will be omitted since it overlaps with the description referring to FIG. 4.

According to embodiments, the display device DD″ may include the first light emitting element group LDG1 including the first light emitting elements LD1 that emit the first light L1 having a center wavelength greater than about 450 nm and less than about 485 nm and the third light emitting element group LDG3 including the third light emitting elements LD3 that emit the third light L3 having a central wavelength less than or equal to about 450 nm. The display device DD″ may include the color conversion pattern CCP that converts the light emitted from the third light emitting element group LDG3.

As the third light emitting element group LDG3 corresponding to the color conversion pattern CCP emits a light having a center wavelength less than or equal to about 450 nm, a light conversion efficiency of the color conversion pattern CCP with respect to a light emitted from the third light emitting element group LDG3 may be improved.

Even in case that a central wavelength of the light emitted from the third light emitting element group LDG3 is less than or equal to about 450 nm, as the first light emitting element group LDG1 corresponding to the light transmission pattern LTP emits a light having a center wavelength greater than about 450 nm and less than about 485 nm, the display device DD″ may have an improved color matching rate.

Therefore, according to embodiments, a light conversion efficiency of the color conversion pattern CCP may be improved without reducing the color matching rate of the display device DD″. Accordingly, a light efficiency and a display quality of the display device DD″ may be improved.

The display device DD″ may further include the second light emitting element group LDG2″ including the second light emitting elements LD2′ that emit the second light L2′ having a central wavelength greater than or equal to about 500 nm and the second light transmission pattern that transmits a light emitted from the second light emitting element group LDG2″.

Therefore, even in case that a central wavelength of the light emitted from the third light emitting element group LDG3 is less than or equal to about 450 nm, as the second light emitting element group LDG2″ corresponding to the second light transmission pattern LTP2 emits a light having a center wavelength greater than or equal to about 500 nm, the display device DD″ may have a further improved color matching rate. Accordingly, a light efficiency and a display quality of the display device DD″ may be further improved.

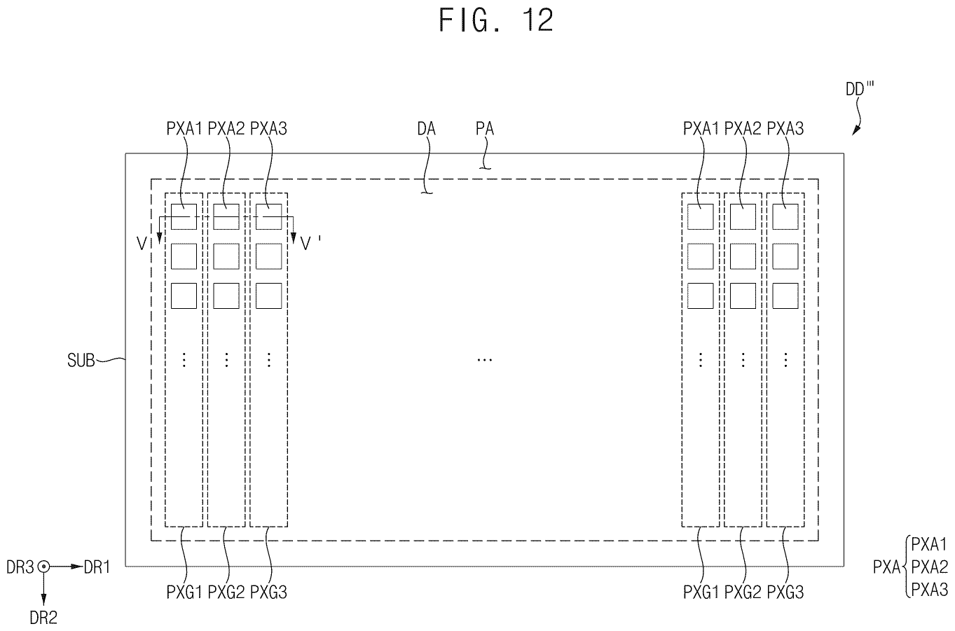

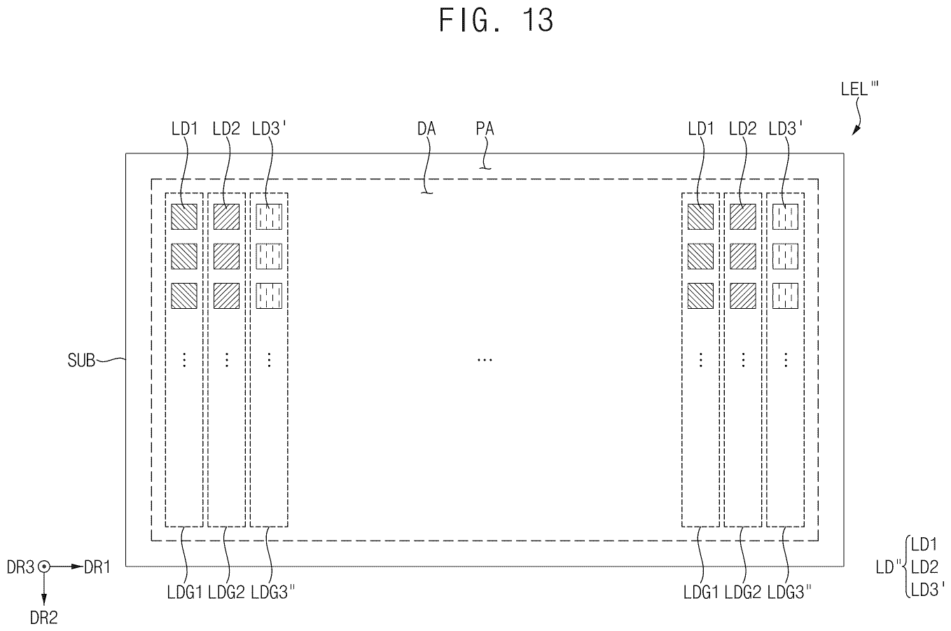

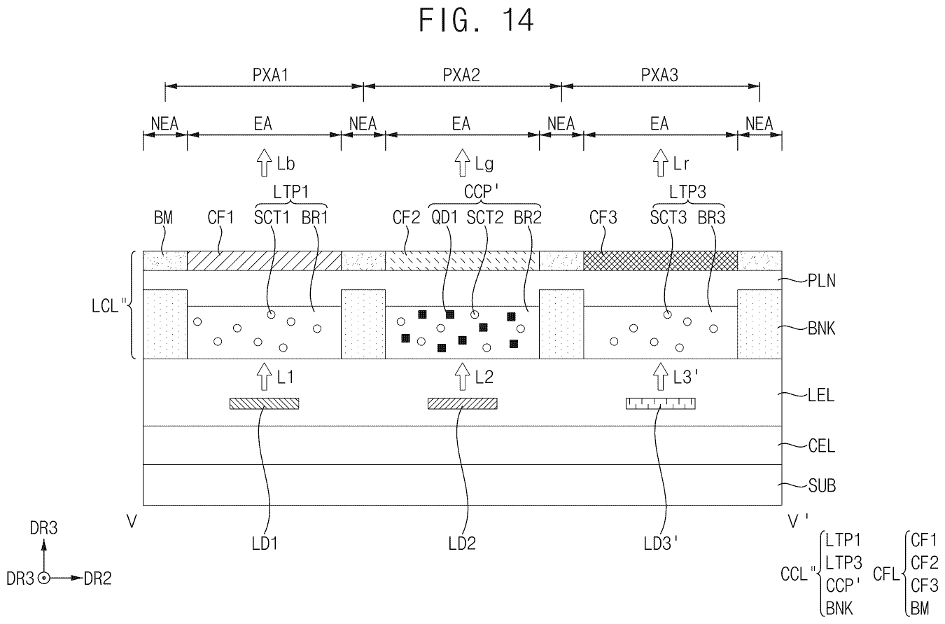

FIG. 12 is a plan view illustrating a display device according to an embodiment. FIG. 13 is a plan view illustrating a light emitting element layer included in the display device of FIG. 12. FIG. 14 is a schematic cross-sectional view taken along line V-V′ of FIG. 12.

Hereinafter, a display device DD′″ according to an embodiment will be described with reference to FIGS. 12 to 14.

The display device DD′″ described with reference to FIGS. 12 to 14 may be substantially the same as the display device DD described with reference to FIGS. 1 to 4 except for including a light emitting element layer LEL′″ and a light conversion layer LCL″. Therefore, overlapping descriptions will be omitted or simplified.

First, referring to FIGS. 12 and 13, the display device DD′″ may include the light emitting element layer LEL′″. The light emitting element layer LEL′″ may be substantially same as the light emitting element layer LEL described with reference to FIGS. 1 to 4 except for including light emitting elements LD″ instead of the light emitting elements LD. Therefore, overlapping descriptions will be omitted or simplified.

The light emitting element layer LEL″ may include the light emitting elements LD″. The light emitting elements LD″ may include the first light emitting elements LD1, the second light emitting elements LD2, and third light emitting elements LD3′.

For example, the light emitting elements LD″ may be substantially same as the light emitting elements LD described with reference to FIGS. 3 and 4 except for including the third light emitting elements LD3′ instead of the third light emitting elements LD3. Accordingly, a detailed description of the first light emitting elements LD1 and the second light emitting elements LD2 will be omitted since it overlaps with the description with reference to FIGS. 3 and 4.

In an embodiment, as illustrated in FIG. 13, the first light emitting element group LDG1 may be a set of the first light emitting elements LD1, the second light emitting element group LDG2 may be a set of the second light emitting elements LD2, and the third light emitting element group LDG3″ may be a set of the third light emitting elements LD3′. In other words, in an embodiment, the first light emitting elements LD1 may be disposed in the first pixel areas PXA1, the second light emitting elements LD2 may be disposed in the second pixel areas PXA2, and the third light emitting elements LD3′ may be disposed in the third pixel areas PXA3. However, the disclosure is not necessarily limited thereto.

A planar arrangement of the light emitting elements LD″ illustrated in FIG. 13 is only an embodiment and may be variously changed according to embodiments.

Further referring to FIG. 14, the circuit element layer CEL, the light emitting element layer LEL′″, and the light conversion layer LCL″ may be disposed on the substrate SUB. A detailed description of the substrate SUB and the circuit element layer CEL will be omitted since it overlaps with the description referring to FIGS. 1 to 4.

In an embodiment, the third light emitting elements LD3′ may be disposed in the light emitting area EA of the third pixel areas PXA3. All of the third light emitting elements LD3′ may emit light of the same component (e.g., center wavelength, color, etc.).

In an embodiment, the third light emitting elements LD3′ may emit a third light L3′ having a central wavelength greater than or equal to about 500 nm. For example, the third light emitting elements LD3′ may emit the third light L3′ of red having a central wavelength greater than or equal to about 500 nm. For example, the central wavelength of the third light L3′ emitted from the third light emitting elements LD3′ may be in a range of about 600 nm to about 780 nm. For example, the central wavelength of the third light L3′ emitted from the third light emitting elements LD3′ may be in a range of about 630 nm to about 700 nm.

For example, in the display device DD′″ according to an embodiment, the first light emitting elements LD1 may emit the first light L1 of blue having the central wavelength greater than about 450 nm and less than about 485 nm, the second light emitting elements LD2 may emit the second light L2′ of blue having a center wavelength less than or equal to about 450 nm, and the third light emitting elements LD3′ may emit the third light L3′ of red having a central wavelength greater than or equal to about 500 nm.

The light conversion layer LCL″ may be disposed on the light emitting element layer LEL′″. In an embodiment, the light conversion layer LCL″ may include a color conversion layer CCL″, the planarization layer PLN, and the color filter layer CFL. For example, the light conversion layer LCL″ may be substantially same as the light conversion layer LCL described with reference to FIGS. 3 and 4 except for including the color conversion layer CCL″ instead of the color conversion layer CCL. Therefore, overlapping descriptions will be omitted or simplified.

The color conversion layer CCL″ may include the first light transmission pattern LTP1, the color conversion pattern CCP, a third light transmission pattern LTP3, and the bank BNK. A detailed description of the bank BNK will be omitted since it overlaps with the description referring to FIG. 4.

The first light transmission pattern LTP1 and the light transmission pattern LTP described with reference to FIG. 4 may have substantially the same structure. For example, in an embodiment, the first light transmission pattern LTP1 may include the first base resin BR1 and the first scatterer SCT1.

In an embodiment, the first light transmission pattern LTP1 may be disposed in the emission area EA of the first pixel areas PXA1. Accordingly, the first light transmission pattern LTP1 may overlap the first light emitting element group LDG1 in a plan view.

The first light transmission pattern LTP1 may transmit the first light L1 emitted from the first light emitting elements LD1 defining the first light emitting element group LDG1 without conversion. In other words, the first light transmission pattern LTP1 may emit a blue light Lb having substantially the same components (e.g., center wavelength, color, etc.) as the first light L1 emitted from the first light emitting elements LD1.

The color conversion pattern CCP′ and the first color conversion pattern CCP1 described with reference to FIG. 4 may have substantially the same structure. For example, in an embodiment, the color conversion pattern CCP′ may include the second base resin BR2 and the first color conversion particle QD1. The color conversion pattern CCP′ may further include the second scatterer SCT2.

In an embodiment, the color conversion pattern CCP′ may be disposed in the emission area EA of the second pixel areas PXA2. Accordingly, the color conversion pattern CCP′ may overlap the second light emitting element group LDG2 in a plan view.

The color conversion pattern CCP′ may convert the second light L2 of blue emitted from the second light emitting elements LD2 defining the second light emitting element group LDG2 into a green light Lg. In other words, the color conversion pattern CCP′ may emit the green light Lg having a different component (e.g., center wavelength, color, etc.) from the second light L2 emitted from the second light emitting elements LD2.

The third light transmission pattern LTP3 may be disposed in the third pixel areas PXA3. Specifically, the third light transmission pattern LTP3 may be disposed in the emission area EA of the third pixel areas PXA3. Accordingly, the third light transmission pattern LTP3 may overlap the third light emitting element group LDG3″ in a plan view. For example, light emitted from the third light emitting element group LDG3″ may be incident on the third light transmission pattern LTP3. For example, the third light L3′ emitted from the third light emitting elements LD3′ defining the third light emitting element group LDG3″ may be incident on the third light transmission pattern LTP3.

The third light transmission pattern LTP3 may transmit the light emitted from the third light emitting device group LDG3″. In other words, the third light transmission pattern LTP3 may emit light having substantially the same components (e.g., center wavelength, color, etc.) as the light emitted from the third light emitting element group LDG3″.

For example, the third light transmission pattern LTP3 may transmit the third light L3′ emitted from the third light emitting elements LD3′ defining the third light emitting element group LDG3″ without converting the third light L3′. In other words, the third light transmission pattern LTP3 may emit a red light Lr having substantially the same components (e.g., center wavelength, color, etc.) as the third light L3′ of red emitted from the third light emitting elements LD3′.

In an embodiment, the third light transmission pattern LTP3 may include the third base resin BR3 and the third scatterer SCT3. A detailed description of the third base resin BR3 and the third scatterer SCT3 will be omitted since it overlaps with the description referring to FIG. 4.

According to embodiments, the display device DD′″ may include the first light emitting element group LDG1 including the first light emitting elements LD1 that emit the first light L1 having a center wavelength greater than about 450 nm and less than about 485 nm and the second light emitting element group LDG2 including the second light emitting elements LD2 that emit the second light L2 having a central wavelength less than or equal to about 450 nm. The display device DD′″ may include the color conversion pattern CCP′ that converts the light emitted from the second light emitting element group LDG2.

As the second light emitting element group LDG2 corresponding to the color conversion pattern CCP′ emits a light having a center wavelength less than or equal to about 450 nm, a light conversion efficiency of the color conversion pattern CCP′ with respect to a light emitted from the second light emitting element group LDG2 may be improved.

Even in case that a central wavelength of the light emitted from the second light emitting element group LDG2 is less than or equal to about 450 nm, as the first light emitting element group LDG1 corresponding to the light transmission pattern LTP emits a light having a center wavelength greater than about 450 nm and less than about 485 nm, the display device DD′″ may have an improved color matching rate.

Therefore, according to embodiments, a light conversion efficiency of the color conversion pattern CCP′ may be improved without reducing the color matching rate of the display device DD′″. Accordingly, a light efficiency and a display quality of the display device DD′″ may be improved.

The display device DD′″ may further include the third light emitting element group LDG3″ including the third light emitting elements LD3′ that emit the third light L3′ having a central wavelength greater than or equal to about 500 nm and the third light transmission pattern that transmits a light emitted from the third light emitting element group LDG3″.

Therefore, even in case that a central wavelength of the light emitted from the second light emitting element group LDG2 is less than or equal to about 450 nm, as the third light emitting element group LDG3″ corresponding to the third light transmission pattern LTP3 emits a light having a center wavelength greater than or equal to about 500 nm, the display device DD′″ may have a further improved color matching rate. Accordingly, a light efficiency and a display quality of the display device DD′″ may be further improved.

Hereinafter, effects of the disclosure will be described with reference to experimental examples and comparative examples. Examples shown below are only an example to aid understanding of the disclosure, and a scope of the disclosure is not limited thereto.

### Experimental Example 1, Experimental Example 2, Experimental Example 3, Comparative Example 1, Comparative Example 2

In Experimental Examples 1 to 3 and Comparative Examples 1 to 2, a manufacturing examples and evaluation methods are as follows.

### 1. Manufacturing Example

### 1) Preparation of Quantum Dot Composition

Scatterers and initiators are added to a propylene glycol methyl ether acetate (PGMEA) solution in which about 40 wt % of quantum dots that absorb blue light and emit green light are dispersed, and stirred for more than 24 hours to obtain a quantum dot composition.

### 2) Preparation of Color Conversion Pattern

The quantum dot composition which is obtained is spin-coated on a glass substrate to obtain a film. The film which is obtained is irradiated with ultraviolet rays using an exposure machine and baked at 180° C. for 30 minutes to obtain a color conversion pattern with a thickness of 10 micrometers that can convert blue light into green light.

### 2. Evaluation Method of Light Conversion Efficiency

### 1) Experimental Example 1

Blue light with a central wavelength of 430 nm was incident on the color conversion pattern which is manufactured, and light conversion efficiency was measured using QE-2000 (Otsuka) equipment. Light conversion efficiency (power conversion efficiency, PCE) was calculated by Equation 1 below.

$$P C E = ( A 2 / A 1 ) \times 100 \qquad [ Equation 1 ]$$

In Equation 1, A1 refers to an area of the blue light absorption spectrum, and A2 refers to an area of an emission spectrum for a converted light. For example, A1 may correspond to an absorption peak area for blue light absorbed by a quantum dot. A2 may correspond to an emission peak area for light converted by the quantum dot.

### 2) Experimental Example 2

Light conversion efficiency was evaluated in the same manner as in Experimental Example 1, except that blue light with a central wavelength of 440 nm was incident on the color conversion pattern.

### 3) Experimental Example 3

Light conversion efficiency was evaluated in the same manner as in Experimental Example 1, except that blue light with a central wavelength of 450 nm was incident on the color conversion pattern.

### 4) Comparative Example 1

Light conversion efficiency was evaluated in the same manner as in Experimental Example 1, except that blue light with a central wavelength of 460 nm was incident on the color conversion pattern.

### 5) Comparative Example 2

Light conversion efficiency was evaluated in the same manner as in Experimental Example 1, except that blue light with a central wavelength of 467 nm was incident on the color conversion pattern.

Table 1 below shows light conversion efficiency of the color conversion pattern measured according to Experimental Examples 1 to 3 and Comparative Examples 1 to 2.

TABLE 1

| | wavelength of | light conversion |
|---|---|---|
| | incident light | efficiency |
| | (nm) | (%) |
| Experimental Example 1 | 430 | 33.7 |
| Experimental Example 2 | 440 | 33.3 |
| Experimental Example 3 | 450 | 30.4 |
| Comparative Example 1 | 460 | 27.0 |
| Comparative Example 2 | 467 | 28.0 |

Referring to Table 1, according to Experimental Examples 1 to 3 in which blue light with a central wavelength of 450 nm or less was incident on the color conversion pattern, light conversion efficiency was greater than 30%, confirming that light conversion efficiency of the color conversion pattern was excellent. On the other hand, according to Comparative Examples 1 and 2 in which blue light with a central wavelength exceeding 450 nm was incident on the color conversion pattern, light conversion efficiency was less than 30%, confirming that light conversion efficiency of the color conversion pattern was degraded compared to the Experimental examples.

### Experimental Example 4, Experimental Example 5, Experimental Example 6, Comparative Example 3, Comparative Example 4

In Experimental Examples 4 to 6 and Comparative Examples 3 to 4, a manufacturing examples and evaluation methods are as follows.

### 1. Manufacturing Example

### 1) Preparation of Quantum Dot Composition

Scatterers and initiators are added to a propylene glycol methyl ether acetate (PGMEA) solution in which about 40 wt % of quantum dots that absorb blue light and emit green light are dispersed, and stirred for more than 24 hours to obtain a quantum dot composition.

### 2) Preparation of Color Conversion Pattern

The quantum dot composition which is obtained is spin-coated on a glass substrate to obtain a film. The film which is obtained is irradiated with ultraviolet rays using an exposure machine and baked at 180° C. for 30 minutes to obtain a color conversion pattern with a thickness of 10 micrometers that can convert blue light into red light.

### 2. Evaluation Method of Light Conversion Efficiency

### 1) Experimental Example 4

Blue light with a central wavelength of 430 nm was incident on the color conversion pattern which is manufactured, and light conversion efficiency was measured using QE-2000 (Otsuka) equipment. Light conversion efficiency (power conversion efficiency, PCE) was calculated by Equation 1 above.

### 2) Experimental Example 5

Light conversion efficiency was evaluated in the same manner as in Experimental Example 4, except that blue light with a central wavelength of 440 nm was incident on the color conversion pattern.

### 3) Experimental Example 6

Light conversion efficiency was evaluated in the same manner as in Experimental Example 4, except that blue light with a central wavelength of 450 nm was incident on the color conversion pattern.

### 4) Comparative Example 3

Light conversion efficiency was evaluated in the same manner as in Experimental Example 4, except that blue light with a central wavelength of 460 nm was incident on the color conversion pattern.

### 5) Comparative Example 4

Light conversion efficiency was evaluated in the same manner as in Experimental Example 4, except that blue light with a central wavelength of 467 nm was incident on the color conversion pattern.

Table 2 below shows light conversion efficiency of the color conversion pattern measured according to Experimental Examples 4 to 6 and Comparative Examples 3 to 4.

TABLE 2

| | wavelength of | light conversion |
|---|---|---|
| | incident light | efficiency |
| | (nm) | (%) |
| Experimental Example 4 | 430 | 37.4 |
| Experimental Example 5 | 440 | 36.6 |
| Experimental Example 6 | 450 | 35.0 |
| Comparative Example 3 | 460 | 34.2 |
| Comparative Example 4 | 467 | 33.2 |

Referring to Table 2, according to Experimental Examples 4 to 6 in which blue light with a central wavelength of 450 nm or less was incident on the color conversion pattern, light conversion efficiency was greater than 35%, confirming that light conversion efficiency of the color conversion pattern was excellent. On the other hand, according to Comparative Examples 3 and 4 in which blue light with a central wavelength exceeding 450 nm was incident on the color conversion pattern, light conversion efficiency was less than 35%, confirming that light conversion efficiency of the color conversion pattern was degraded compared to the Experimental examples.

### Experimental Example 7, Experimental Example 8, Comparative Example 5, Comparative Example 6

In Experimental Examples 7 to 8 and Comparative Examples 5 to 6, display devices were manufactured under the same conditions, except for a central wavelength of a blue light emitted from the light emitting element corresponding to the first pixel area that emits a blue light. In each of Experimental Examples 7 to 8 and Comparative Examples 5 to 6, central wavelengths of light emitted by the light emitting elements corresponding to the first pixel area emitting a blue light, the second pixel area emitting a green light, and the third pixel area emitting a red light are shown in Table 3 below.

In Table 3, color matching rate was evaluated based on the BT2020 color gamut.

TABLE 3

| | central | central | central | |
|---|---|---|---|---|
| | wavelength | wavelength | wavelength | |
| | of a blue | of a blue | of a blue | |
| | light emitted | light emitted | light emitted | |
| | from a light | from a light | from a light | |
| | emitting | emitting | emitting | |
| | element | element | element | |
| | correspond- | correspond- | correspond- | color |
| | ing to the | ing to the | ing to the | matching |
| | first pixel | second pixel | third pixel | rate |
| | area (nm) | area (nm) | area (nm) | (%) |
| Experimental | 460 | 430 | 430 | 90.0 |
| Example 7 | | | | |
| Experimental | 467 | 430 | 430 | 90.7 |
| Example 8 | | | | |
| Comparative | 440 | 430 | 430 | 87.1 |
| Example 5 | | | | |
| Comparative | 450 | 430 | 430 | 88.3 |
| Example 6 | | | | |

Referring to Table 3, according to Experimental Examples 7 and 8, where the light emitting element disposed in the first pixel area emitting blue light emits blue light having a center wavelength greater than 450 nm and less than 485 nm, even in case that the light emitting elements respectively disposed in the second pixel area that emits green light and the third pixel area that emits red light emit blue light having a center wavelength of 450 nm or less, the color matching rate of the display device was greater than 90%, confirming that the color matching rate of the display device was excellent. On the other hand, according to Comparative Examples 5 and 6, where the light emitting element disposed in the first pixel area emitting blue light emits blue light having a center wavelength of 450 nm or less, in case that the light emitting elements respectively disposed in the second pixel area that emits green light and the third pixel area that emits red light emit blue light having a center wavelength of 450 nm or less, the color matching rate of the display device was less than 90%, confirming that the color matching rate of the display device was degraded compared to the Experimental examples.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first light emitting element group including at least one first light emitting element which emits a first light having a central wavelength greater than about 450 nm and less than about 485 nm;
a second light emitting element group including at least one second light emitting element which emits a second light having a central wavelength less than or equal to about 450 nm;
a third light emitting element group including at least one third light emitting element which emits a third light having a central wavelength less than or equal to about 450 nm; and
a color conversion layer disposed on the first light emitting element group, the second light emitting element group, and the third light emitting element group and including a first color conversion pattern which converts a light emitted from the second light emitting element group and a second color conversion pattern which converts a light emitted from the third light emitting element group.

2. The display device of claim 1, wherein
the color conversion layer further includes a light transmission pattern which transmits a light emitted from the first light emitting element group,
the light transmission pattern overlaps the first light emitting element group in a plan view,
the first color conversion pattern overlaps the second light emitting element group in the plan view, and
the second color conversion pattern overlaps the third light emitting element group in the plan view.

3. The display device of claim 2, wherein
the light transmission pattern includes a first scatterer, and
each of the first color conversion pattern and the second color conversion pattern includes a quantum dot.

4. The display device of claim 3, wherein each of the first color conversion pattern and the second color conversion pattern further includes a second scatterer.

5. The display device of claim 1, wherein
the first color conversion pattern converts the light emitted from the second light emitting element group into green light, and
the second color conversion pattern converts the light emitted from the third light emitting element group into red light.

6. The display device of claim 5, wherein
a light conversion efficiency of the first color conversion pattern with respect to the light emitted from the second light emitting element group is greater than or equal to about 30%, and
a light conversion efficiency of the second color conversion pattern with respect to the light emitted from the third light emitting element group is greater than or equal to about 35%.

7. The display device of claim 1, wherein the central wavelength of the first light emitted by the at least one first light emitting element is in a range of about 460 nm to about 470 nm.

8. The display device of claim 1, wherein a color matching rate of the display device is greater than or equal to about 90%.

9. The display device of claim 1, further comprising:
a color filter layer disposed on the color conversion layer.

10. The display device of claim 1, wherein each of the at least one first light emitting element, the at least one second light emitting element, and the at least one third light emitting element is an ultra-small light emitting element.

11. The display device of claim 1, wherein the central wavelength of the second light emitted from the at least one second light emitting element and the central wavelength of the third light emitted from the at least one third light emitting element are same.

12. The display device of claim 1, wherein the central wavelength of the second light emitted from the at least one second light emitting element and the central wavelength of the third light emitted from the at least one third light emitting element are different from each other.

13. The display device of claim 12, wherein the second light emitting element group further includes the at least one third light emitting element, and
the third light emitting element group further includes the at least one second light emitting element.

14. A display device comprising:
a first light emitting element group including at least one first light emitting element which emits a first light having a central wavelength greater than about 450 nm and less than about 485 nm;
a second light emitting element group including at least one second light emitting element which emits a second light having a central wavelength greater than or equal to about 500 nm;
a third light emitting element group including at least one third light emitting element which emits a third light having a central wavelength less than or equal to about 450 nm; and
a color conversion layer disposed on the first light emitting element group, the second light emitting element group, and the third light emitting element group and including a color conversion pattern which converts a light emitted from the third light emitting element group.

15. The display device of claim 14, wherein
the color conversion layer further includes:
a first light transmission pattern which transmits a light emitted from the first light emitting element group; and
a second light transmission pattern which transmits a light emitted from the second light emitting element group,
the first light transmission pattern overlaps the first light emitting element group in a plan view,
the second light transmission pattern overlaps the second light emitting element group in the plan view, and
the color conversion pattern overlaps the third light emitting element group in the plan view.

16. The display device of claim 15, wherein
each of the first light transmission pattern and the second light transmission pattern includes a first scatterer, and
the color conversion pattern includes a quantum dot and a second scatterer.

17. The display device of claim 14, wherein the central wavelength of the first light emitted from the at least one first light emitting element is in a range of about 460 nm to about 470 nm.

18. The display device of claim 14, wherein a color matching rate of the display device is greater than or equal to about 90%.

19. The display device of claim 14, further comprising:
a color filter layer disposed on the color conversion layer.

20. The display device of claim 14, wherein each of the at least one first light emitting element, the at least one second light emitting element, and the at least one third light emitting element is an ultra-small light emitting element.
